(19) United States
(12) Patent Application Publication
(10) Pub. No.: US 2025/0357130 A1
(43) Pub. Date: Nov. 20, 2025

(54) MANUFACTURING PROCESS COMPRISING AN ASSEMBLY OF SEMICONDUCTOR WAFERS AND CORRESPONDING SEMICONDUCTOR DEVICE

(71) Applicant: STMicroelectronics International N.V., Geneva (CH)

(72) Inventor: Come De Buttet, Lumbin (FR)

(21) Appl. No.: 19/097,287

(22) Filed: Apr. 1, 2025

(30) Foreign Application Priority Data
May 15, 2024 (FR) FR2404953

(51) Int. Cl. H01L 21/304; H01L 21/18; H01L 21/77

(52) U.S. Cl. CPC H01L 21/304; H01L 21/185; H01L 21/77

(57) ABSTRACT

A method for manufacturing integrated circuits comprises assembling a first semiconductor wafer including a first interconnecting region and a second semiconductor wafer including a second interconnecting region, including placing the first interconnecting region in contact with the second interconnecting region in a contact interface, and machining the assembly, including bevel polishing the assembly of the first interconnecting region and the second interconnecting region, and removing a circumferential annular region of the contact interface.

### CROSS-REFERENCE TO RELATED APPLICATIONS

This application claims priority to French Application No. FR2404953, filed on May 15, 2024, which application is hereby incorporated herein by reference.

### TECHNICAL FIELD

Embodiments and implementations relate to integrated circuit devices and methods, in particular integrated circuits of the 3D technology type, such as technologies that use a hybrid bonding technique.

### BACKGROUND

Hybrid bonding is a technique that makes it possible to assemble two semiconductor wafers together, or two chips together, or chips on a wafer.

Assembling is typically carried out on the upper surfaces of interconnecting regions formed on each wafer, which are moved closer together in order to be placed in contact, forming permanent metal-to-metal (typically copper) bonds between metal pads and dielectric-to-dielectric (typically SiO2) bonds elsewhere.

### SUMMARY

Conventionally, defects in the bonding (such as imperfect bonds, voids, etc.) are present at the wafer edge and may cause delaminations propagating into the lay-ups of the bonded regions.

Thus, the outer portion of the structure of the two bonded wafers is typically cut around the entire contour of the structure, via a trimming technique, such as conventionally using a rotary cutting disc to trim the structure by abrasion.

This conventional machining of the assembled structure of two wafers makes it possible to reduce the risk of delamination generated by the bonding defects, but generates significant mechanical stresses during cutting that may cause delaminations, in particular if the interconnecting regions include relatively fragile materials, such as low permittivity dielectric materials.

In addition, this type of conventional machining cutting the contour of the structure of assembled wafers, generates an abrupt edge, typically perpendicular to the plane of the wafers (the bonding plane), as well as local defects on the trimmed edge, such as flaked pieces and a relatively high roughness.

Consequently, a subsequent step of depositing fluid material, typically a resin covering the assembled wafers, may generate a formation of a circumferential bead caused by an accumulation of the fluid retained on the edge by its surface tension.

It will be noted that the roughness of conventional trimmings is effectively high, by order of magnitude, relative to the respective viscosity and surface tension of typical resins, which contributes to blocking the flow and to the accumulation of fluid.

The flaked pieces (e.g., portions broken from the edge of the structure) and the resin beads, may in practice advance to a position facing the semiconductor chips that may be functional all other things being equal. This results in a loss of efficiency.

Thus, there is a need to improve the efficiency of manufacturing methods comprising an assembly of wafers of the hybrid bonding type.

In this respect, a method is proposed for manufacturing integrated circuits comprising: a step of assembling a first semiconductor wafer including a first interconnecting region and a second semiconductor wafer including a second interconnecting region, comprising placing the first interconnecting region in contact with the second interconnecting region in a contact interface; and a step of machining comprising bevel polishing the assembly of the first interconnecting region and the second interconnecting region, removing a circumferential annular region of the contact interface.

On the one hand, the bevel polishing generates mechanical stresses in the bonded layers (e.g., at the contact interface) that are very moderate, which reduces the risk of delamination and splintering of flakes. As a result, the moderate mechanical stresses also make it possible to reduce the risk of delamination in the event of low permittivity dielectric use (as opposed to the trimming technique that is to be avoided in the event of use of low permittivity materials).

On the other hand, the bevel polishing generates a profile that is not abrupt (and of which the angle of the bevel can usually be adjusted if necessary), which makes it possible to obtain a uniform covering in the event of deposition of a fluid material.

Advantageously, the method thus further includes a step of spin coating a fluid material on the machined assembly of the first wafer and of the second wafer.

For example, the implementation of the bevel polishing may easily be configured to have a sufficiently small inclination, relative to the viscosity of the fluid material, in order to obtain a deposition of the fluid material of uniform thickness, such as without the formation of a circumferential bead.

According to one implementation, the bevel polishing is configured to have an inclination of an angle between 10 degrees and 45 degrees in relation to the plane of the contact interface.

For example, the bevel polishing may easily be configured to have a sufficiently fine surface roughness, relative to the viscosity of the fluid material, in order to obtain a deposition of the fluid material of uniform thickness, e.g., without the formation of a circumferential bead.

According to one implementation, the bevel polishing is configured to have a surface roughness of which the size, in nanometers “nm”, is between 100 nm and 1,000 nm.

According to one implementation, the bevel polishing comprises rotating the assembly of the first wafer and of the second wafer, and pressing a polishing strip against the edge of the assembly and with an inclination defining the angle of the bevel.

According to one implementation, at least one of the first interconnecting region and the second interconnecting region includes a low permittivity dielectric material layer.

Conventionally, in the field of semiconductors, a low permittivity dielectric material is defined as being a material of which the relative dielectric constant is lower than that of silicon dioxide.

According to one implementation, the method further comprises, before the assembly step, a step of preparing the first semiconductor wafer, including a first machining removing a circumferential portion of the first interconnecting region, so as to shape a clean edge capable of being placed in contact with a surface of the second interconnecting region and of delimiting the contour of the circumferential annular region of the contact interface.

Furthermore, after the assembly step and before machining the contact interface, the method may include a step of thinning the first semiconductor wafer turned over, from the side of the wafer opposite the side of the contact interface.

According to another aspect, a semiconductor device is also proposed including a first semiconductor wafer including a first interconnecting region assembled with a second semiconductor wafer including a second interconnecting region, the first interconnecting region being in contact with the second interconnecting region in a contact interface, the assembly of the first interconnecting region and of the second interconnecting regions comprising a machined portion, bevel polished, in a circumferential annular region of the contact interface.

According to one embodiment, the semiconductor device further includes, on the assembly of the first wafer and of the second wafer, a layer of a material obtained by spin coating a fluid material.

According to one embodiment, the bevel polished portion has an inclination of an angle between 10 degrees and 45 degrees in relation to the plane of the contact interface.

According to one embodiment, the bevel polished portion has a surface roughness of which the size, in nanometers “nm”, is between 100 nm and 1,000 nm.

According to one embodiment, at least one of the first interconnecting region and the second interconnecting region includes a low permittivity dielectric material layer.

### BRIEF DESCRIPTION OF THE DRAWINGS

Other advantages and features of the invention will become apparent upon examining the detailed description of non-limiting embodiments and implementations, and from the appended drawings, wherein figures:

FIGS. 1A-1F illustrate a method of manufacturing a 3D technology integrated circuit;

FIG. 2 illustrates geometrical and structural features of a bevel machined structure; and

FIG. 3 illustrates graph of an example result obtained in the uniformity of the fluid material thickness.

### DETAILED DESCRIPTION OF ILLUSTRATIVE EMBODIMENTS

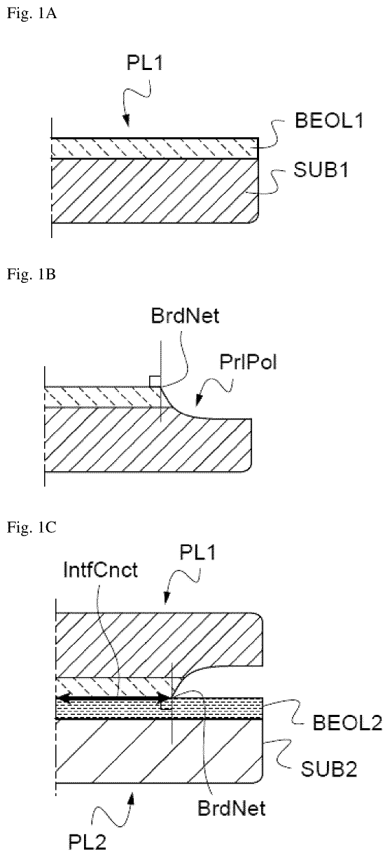

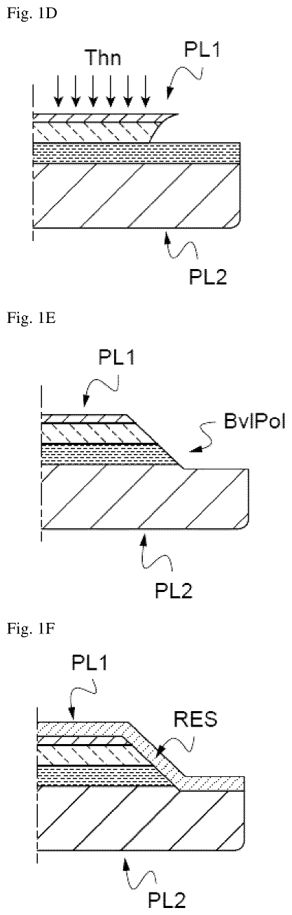

FIGS. 1A to 1F illustrate results of steps of one example of method for manufacturing integrated circuits of the 3D technology type, such as a method comprising an assembly of two semiconductor wafers PL1, PL2.

Each wafer PL1, PL2 includes chips (or dies) facing one another in the assembly forming 3D structures capable of being individualized to form integrated circuits.

Figure iA illustrates a first semiconductor wafer PL1 including a first semiconductor substrate SUB1, and a first interconnecting region BEOL1.

The first semiconductor substrate SUB1 includes the production of chips intended to have a first function in the technology of the first wafer PL1, for example mainly photonic or photoelectric technology, such as imager technology.

Thus, for example, the chips of the first wafer PL1 include pixel matrices, summarily provided with photosensitive semiconductor structures and local circuits such as transistors, transfer gates, capacitive nodes, etc.

The first interconnecting region BEOL1 includes metal levels and inter-metal dielectric layers, forming a network configured to electrically couple the components of the chips with one another and for example with external coupling elements, such as metal contact pads.

In cutting-edge technologies, the inter-metal dielectric layers of the first interconnecting region BEOL1 may include formations of low permittivity dielectric material. Low permittivity dielectrics have advantageous electrical properties, particularly a lower parasitic capacitance at a given thickness, but are typically less resistant to mechanical stresses.

It is reminded that a low permittivity dielectric material is defined, conventionally in the field of semiconductors, as a material of which the relative dielectric constant is lower than that of silicon dioxide. The relative dielectric constant of silicon dioxide “SiO2” equals k_SiO2=3.9 and is equal to the ratio of the permittivity of SiO2 divided by the permittivity of the void, ε_SiO2/ε_0=k_SiO2, where ε_0=8.854×10-6 pF/μm. There are many materials having lower relative dielectric constants, particularly: fluorine-doped silicon dioxide, carbon-doped silicon dioxide, porous silicon dioxide, porous carbon-doped silicon dioxide.

FIG. 1B illustrates the result of a step of preparing the first wafer PL1 before assembling, in particular in view of the hybrid bonding described below in relation to FIG. 1C.

The step of preparing the first wafer PL1 includes a preliminary machining PrlPol making it possible to prepare the edge of the first interconnecting region BEOL1.

Indeed, during the preliminary machining PrlPol, a circumferential portion of the first interconnecting region BEOL1 is removed, so as to shape a clean edge BrdNet suitable for generating bonding by atomic bonds (for example of the Van der Waals bond type) by being placed in contact with a surface IntfCnct (FIG. 1C) of the second interconnecting region BEOL2.

For example, the clean edge BrdNet is suitable in this respect in that it is free of burrs and flakes, and in that the rim between the edge BrdNet and the surface (IntfCnct) of the first interconnecting region BEOL1 has a right-angled break.

Nominally, in the absence of preliminary machining PrlPol, the rim around the contour of the first interconnecting region BEOL1 may have a profile of the chamfer type with an angle less than 90 degrees, potentially conducive to the propagation of a delamination in relation to the flat surface (BEOL2).

Furthermore, the clean edge BrdNet thus formed, will delimit the circumference of the contact interface IntfCnt between the first wafer PL1 and the second wafer PL2.

In this respect, reference is made to FIG. 1C.

FIG. 1C illustrates the assembly of the first wafer PL1 with the second semiconductor wafer PL2.

The second wafer PL2 includes a second semiconductor substrate SUB2, and a second interconnecting region BEOL2.

The second semiconductor substrate SUB2 includes the production of chips intended to have a second function in the technology of the second wafer PL2, for example mainly a logic technology such as microcontroller technology.

Thus, for example, the chips of the second wafer PL2 summarily include logic circuits, memory circuits, or also power supply management circuits.

The second interconnecting region BEOL2 also includes metal levels and inter-metal dielectric layers, forming a network configured to electrically couple the components of the chips with one another and for example with external coupling elements, such as metal contact pads.

The inter-metal dielectric layers of the second interconnecting region BEOL2, may also include formations of low permittivity dielectric material.

The assembly step comprises placing in contact the first interconnecting region BEOL1 of the first wafer PL1 with the second interconnecting region BEOL2 of the second wafer PL2 in a contact interface IntfCnct.

The contact interface IntfCnct is thus defined by the upper surfaces of the first interconnecting region BEOL1 and of the second interconnecting region BEOL2, placed in contact with one another.

In particular, the contact interface IntfCnct may include the entire surface of the upper side of the first interconnecting region BEOL1 delimited around its circumference by the edge BrdNet shaped in the step PrlPol described above in relation to FIG. 1B.

The upper surfaces of the first and of the second interconnecting region BEOL1, BEOL2, are thus moved closer together so as to generate a permanent bonding, by forming atomic bonds (for example of the Van der Waals bond type) between the metal and dielectric materials exposed on the upper surfaces.

In this respect, the first interconnecting region BEOL1 and the second interconnecting region BEOL2 include pads made of metal, for example copper, with a last dielectric layer, according to a mirror arrangement facing one another.

FIG. 1D illustrates the result of a step of thinning Thn the first wafer PL1 from its back side after bonding, in particular for the case where the first wafer PL1 includes back side illumination imager technology.

Indeed, in this case, the first substrate SUB1 is thinned from the back side opposite the side on which the first interconnecting region BEOL1, is produced, so that the photosensitive formations at the front side of the substrate SUB1 are exposed to an incident signal reaching the back side.

FIG. 1E illustrates the result of the advantageous machining step comprising bevel polishing BvlPol the assembly of the two wafers PL1, PL2.

The bevel polishing BvlPol is configured to form a bevel, e.g., cutting with a low inclination in relation to the assembled surface of the wafers PL1, PL2, e.g., the back side of the first substrate SUB1.

Low inclination means a slope having an angle in relation to the surface of the assembled wafers PL1, PL2 strictly less than 90 degrees, for example less than 45 degrees, or even less than 30 degrees. It will be noted that to form the bevel, the angle is not zero, e.g., the inclination is not flat, an angle greater than 10 degrees or 11 degrees may be provided.

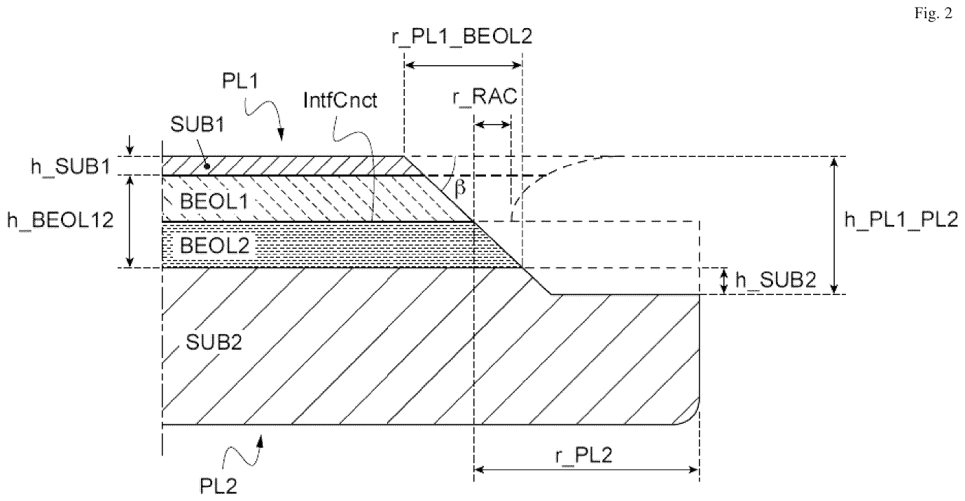

The bevel polishing BvlPol is positioned to remove a circumferential annular region r_RAC (FIG. 2) of the contact interface IntfCnct, in particular in the first interconnecting region BEOL1 and in the second interconnecting region BEOL2.

The bevel polishing machining technique may comprise rotating the assembly of the first wafer PL2 and of the second wafer PL2, and pressing a polishing strip against the circumferential edge of the assembly and with an angle defining the inclination of the bevel.

This type of bevel polishing BvlPol technique generates mechanical stresses in the bonded layers (e.g., at the contact interface IntfCnct) that are very moderate, which reduces the risk of delamination and splintering of flakes, and particularly in the event of use of low permittivity dielectrics in the interconnecting regions BEOL1, BEOL2.

Furthermore, the bevel polishing generates a profile that is not abrupt (and of which the angle of the bevel can usually be adjusted if necessary), which makes it possible to obtain a uniform covering in the event of deposition of a fluid material RES.

In this respect, reference is made to FIG. 1F.

FIG. 1F illustrates the result of a step of spin coating a fluid material RES on the machined assembly of the first wafer PL1 and of the second wafer PL2.

Typically, the fluid material RES thus deposited is intended to solidify, and may for example form optical filters, such as blue, green, red and/or infra-red selective filters.

For example, the implementation of the bevel polishing BvlPol (FIG. 1E) may easily be configured to have a sufficiently small inclination, relative to the viscosity of the fluid material RES, in order to obtain a deposition of the fluid material of uniform thickness, e.g., constant throughout the entire deposition and in particular without forming a circumferential bead.

In this respect, the bevel polishing BvlPol is for example configured to have an inclination of an angle between 10 degrees and 45 degrees in relation to the plane of the contact interface.

For example, the bevel polishing BvlPol may easily be configured to have a sufficiently fine surface roughness, relative to the viscosity of the fluid material, in order to obtain a deposition of the fluid material of uniform thickness, e.g., constant throughout the entire deposition and in particular without forming a circumferential bead.

In this respect, the bevel polishing BvlPol is for example configured to have a surface roughness of which the size, expressed in nanometers “nm”, is between 100 nm and 1,000 nm.

According to another point of view, FIG. 1F shows a semiconductor device, for example called 3D assembly, including a first semiconductor wafer PL1 including a first interconnecting region BEOL1 assembled with a second semiconductor wafer PL2 including a second interconnecting region BEOL2, the first interconnecting region being in contact with the second interconnecting region in a contact interface IntfCnct; the assembly of the first interconnecting region and of the second interconnecting region comprising a machined portion BvlPol, bevel polished, in a circumferential annular region of the contact interface; and further covered by a layer of uniform thickness of a solidified material RES, capable of having been obtained by spin coating a fluid material RES (before solidification).

The semiconductor device of FIG. 1F is for example intended for an Electrical Wafer Sorting (EWS) step making it possible to select the assembled chips of the first wafer PL1 and of the second wafer PL2 that are functional, before cutting the 3D wafers and packaging the chips into plastic boxes.

FIG. 2 illustrates geometrical and structural features of the bevel machined structure; as described above in relation to FIG. 1E. The contour of the machined structure, as described above in relation to FIG. 1D, is also shown in dashed lines.

All of the measurements expressed below are given by way of example and order of magnitude.

The distances shown vertically in the plane in FIG. 2 correspond to vertical distances in the assembly PL1, PL2, and are named thicknesses or heights.

The distances shown horizontally in the plane in FIG. 2 correspond to radial distances in the assembly PL1, PL2, given that the wafers have a disc shape in the plane perpendicular to the plane of the figure. Thus, the distances shown in the horizontal orientation of FIG. 2 correspond to the width of a ring substantially located around the circumference of the discs of the wafers PL1, PL2.

The thickness h_SUB1 of the first substrate SUB1 remaining after thinning Thn, may be between 6 μm (micrometers) and 10 μm (micrometers).

The thickness h_BEOL12 of the superposition of the first interconnecting region BEOL1 and of the second interconnecting region BEOL2 may be of 35 μm (micrometers), with for example 20 μm (micrometers) for the first region BEOL1 and 15 μm for the second region BEOL2.

The radial distance r_PL1_BEOL2 of the portions of the first wafer PL1 and of the second interconnecting region BEOL2 removed by the machining step BvlPol, is advantageously as narrow as possible, and is for example limited between 200 and 300 μm (micrometers).

The radial distance R_PL2 of the portions of the second wafer PL2 removed by the machining step BvlPol is advantageously greater than the radial distance at which is positioned the clean edge BrdNet of the first wafer PL1 formed during the preparation step described above in relation to FIG. 1B, for example greater than 3 mm (millimeter).

Indeed, this makes it possible to position the bevel polishing BvlPol so as to remove a circumferential annular region r_RAC of the contact interface IntfCnct obtained during the bonding, as described above in relation to FIG. 1C.

Thus, although advantageously prepared by the preliminary machining step PrlPol, the bonding of the edge BrdNet of the first interconnecting region BEOL1 on the flat upper surface of the second wafer PL2, nevertheless remains the starting point and possibly the cause of delamination at the contact interface IntfCnct.

Thus, the bevel removal of this circumferential annular region r_RAC from the contact interface IntfCnct further makes it possible to reduce the risk of delamination of the structure at this location.

The height h_SUB2 machined vertically in the second substrate SUB2 is advantageously as small as possible.

The angle of the bevel β is for example between 10 degrees and 30 degrees, for example ii degrees. Indeed, the angle β particularly makes it possible to meet the aforementioned constraints, while making it possible to deposit fluid material RES of uniform thickness.

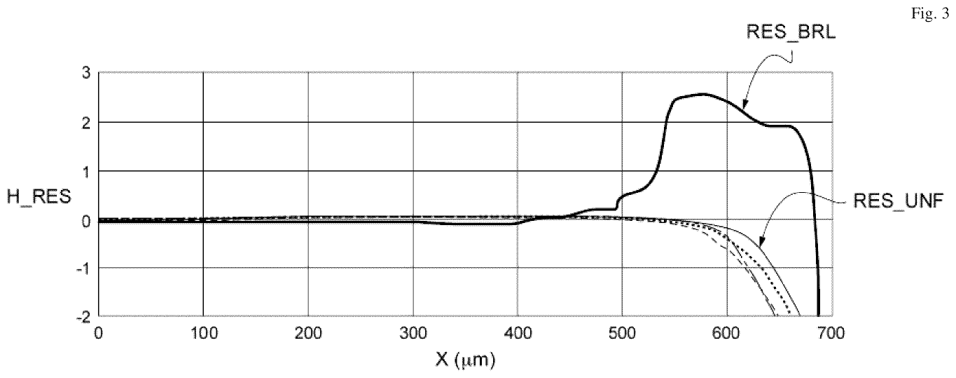

FIG. 3 shows an example of result obtained in the uniformity of the thickness of the fluid material RES.

The curves RES_UNF illustrate the measured heights h_RES of a fluid material RES spin coated on the bevel machined assembly of the first wafer PL1 and of the second wafer PL2 as described above in relation to FIGS. 1E and 1F, along a radial distance X reaching the edge of the assembly of wafers PL1, PL2 beyond the maximum dimension (700 μm).

The formation RES_UNF thus obtained has a perfectly uniform thickness, e.g., constant throughout the entire deposition and in particular without the formation of a circumferential bead.

The curve RES_BRL illustrates the measured heights h_RES of a fluid material RES spin coated on an assembly conventionally machined in vertical operation (slope at 90 degrees) of the first wafer and of the second wafer, along a radial distance X reaching the edge of the assembly of the wafers beyond the maximum dimension (700 μm).

The formation RES_BRL thus obtained has a variable thickness, substantially uniform up to a circumferential region located between the dimensions 450 μm and 700 μm, wherein an accumulation of material generates the formation of a circumferential bead that may reach 2 to 3 μm in height. Indeed, the fluid material may be retained by a surface tension effect on the rim of the edge at 90 degrees of the structure, and thus accumulate in height if not evacuated radially outwards.

In summary, the method for manufacturing integrated circuits described in relation to FIGS. 1A to 1F and FIGS. 2 and 3, includes bevel polishing during the end of production line step after the bonding and thinning steps on 3D wafer assembly technologies, making it possible to solve three problems in particular: the delamination and the flaking of the layers bonded on the edge of the assembly of wafers, the problems of circumferential bosses (or beads) and of uneven patterns of the fluid material (resin) RES, and the risk of cross contamination of the equipment of an industrial production line with this accumulation of resin.

What is claimed is:

1. A method comprising:
assembling a first semiconductor wafer including a first interconnecting region and a second semiconductor wafer including a second interconnecting region into an assembly, the assembling comprising placing the first interconnecting region in contact with the second interconnecting region in a contact interface; and
machining the assembly, the machining comprising:
bevel polishing the first interconnecting region and the second interconnecting region of the assembly; and
removing a circumferential annular region of the contact interface.

2. The method according to claim 1, further comprising spin coating a fluid material on the machined assembly of the first semiconductor wafer and of the second semiconductor wafer.

3. The method according to claim 1, wherein the bevel polishing has an inclination of an angle between 10 degrees and 45 degrees relative to a plane of the contact interface.

4. The method according to claim 1, wherein the bevel polishing generates a surface roughness of between 100 nanometers (nm) and 1,000 nm in a beveled portion of the assembly.

5. The method according to claim 1, wherein the bevel polishing comprises:
rotating the assembly of the first semiconductor wafer and of the second semiconductor wafer; and
pressing a polishing strip against an edge of the assembly and with an inclination defining a bevel angle.

6. The method according to claim 1, wherein at least one of the first interconnecting region and the second interconnecting region includes a low permittivity dielectric material layer.

7. The method according to claim 1, further comprising, before the assembling, preparing the first semiconductor wafer, including preliminary machining removing a circumferential portion of the first interconnecting region, so as to shape a clean edge capable of being placed in contact with a surface of the second interconnecting region and delimiting a contour of the circumferential annular region of the contact interface.

8. A semiconductor device comprising:
an assembly including a first semiconductor wafer having a first interconnecting region assembled with a second semiconductor wafer having a second interconnecting region, wherein the first interconnecting region is in contact with the second interconnecting region in a contact interface; and
a bevel polished portion of the first interconnecting region and of the second interconnecting region, wherein the bevel polished portion is in a circumferential annular region of the contact interface.

9. The semiconductor device according to claim 8, further comprising, on the assembly of the first semiconductor wafer and of the second semiconductor wafer, a spin coated material layer.

10. The semiconductor device according to claim 8, wherein the bevel polished portion has an inclination of an angle between 10 degrees and 45 degrees in relation to a plane of the contact interface.

11. The semiconductor device according to claim 8, wherein the bevel polished portion has a surface roughness of between 100 nanometers (nm) and 1,000 nm.

12. The semiconductor device according to claim 8, wherein at least one of the first interconnecting region and the second interconnecting region includes a low permittivity dielectric material layer.

13. The semiconductor device according to claim 8, wherein each of the first interconnecting region and the second interconnecting region includes a low permittivity dielectric material layer.

14. A method comprising:
placing a first interconnecting region of a first semiconductor wafer in contact with a second interconnecting region of a second semiconductor wafer in a contact interface, to form an assembly; and
bevel polishing the first interconnecting region and the second interconnecting region of the assembly to remove a circumferential annular region of the contact interface.

15. The method according to claim 14, further comprising spin coating a fluid material on the assembly of the first semiconductor wafer and of the second semiconductor wafer.

16. The method according to claim 14, wherein the bevel polishing has an inclination of an angle between 10 degrees and 45 degrees relative to a plane of the contact interface.

17. The method according to claim 14, wherein the bevel polishing generates a surface roughness of between 100 nanometers (nm) and 1,000 nm in a beveled portion of the assembly.

18. The method according to claim 14, wherein the bevel polishing comprises:
rotating the assembly of the first semiconductor wafer and of the second semiconductor wafer; and
pressing a polishing strip against an edge of the assembly and with an inclination defining a bevel angle.

19. The method according to claim 14, wherein at least one of the first interconnecting region and the second interconnecting region includes a low permittivity dielectric material layer.

20. The method according to claim 14, further comprising, before the placing, preparing the first semiconductor wafer, including preliminary machining removing a circumferential portion of the first interconnecting region, so as to shape a clean edge capable of being placed in contact with a surface of the second interconnecting region and delimiting a contour of the circumferential annular region of the contact interface.
